(19) United States
(12) Patent Application Publication
(10) Pub. No.: US 2010/0301332 A1
(43) Pub. Date: Dec. 2, 2010

(54) Detecting a Fault State of a Semiconductor Arrangement

(76) Inventors: Donald Dibra, Muenchen (DE); Jens Barrenscheen, Muenchen (DE)

Correspondence Address: SLATER & MATSIL, L.L.P., 17950 PRESTON ROAD, SUITE 1000, DALLAS, TX, 75252, US

(21) Appl. No.: 12/474,959

(22) Filed: May 29, 2009

(51) Int. Cl. H01L 23/58

(52) U.S. Cl. 257/48; 257/E23.141; 257/E23.079; 257/467

(57) ABSTRACT

Disclosed is a method for detecting a mechanical fault state of a semiconductor arrangement, using a temperature profile.

### TECHNICAL FIELD

The present disclosure relates to a method for detecting a fault state of a semiconductor arrangement and to a semiconductor arrangement.

### BACKGROUND

A semiconductor arrangement includes at least one semiconductor body (die) in which at least one semiconductor component is integrated. The semiconductor body may have at least one of electrical and thermal contacts that serve for electrically contacting the semiconductor body or for thermally connecting the semiconductor body to a cooling element. The semiconductor body, and in particular the contacts, are subject to fatigue and wear which may result in an interruption of the electrical or thermal contact.

Such fatigue induced interruption of an electrical or thermal contact may result in damage of the semiconductor arrangement or, what could be even more relevant, of a circuit in which the semiconductor arrangement is employed. There is therefore a need for detecting fatigue induced fault states of a semiconductor arrangement.

### SUMMARY OF THE INVENTION

One aspect of the present disclosure relates to a method for detecting a mechanical fault state of a semiconductor arrangement, the method comprising: obtaining a temperature profile that includes n temperatures, with n≧2, by determining the temperature at n different positions of the semiconductor arrangement; evaluating the temperature profile by evaluating the relationship of at least two of the n temperatures of the temperature profile; detecting the presence of the fault state dependent on the result of evaluating the temperature profile.

A further aspect relates to a semiconductor arrangement comprising: n temperature sensors, with n≧2, that are located at n different positions of the semiconductor arrangement and that provide temperature signals; an evaluation circuit that is connected to the temperature sensors and that is adapted to evaluate the relationship of at least two of the n temperatures of the temperature profile, that provides a state signal indicating one of a normal state or a mechanical fault state dependent on the result of evaluating the temperature profile.

### BRIEF DESCRIPTION OF THE DRAWINGS

Examples will now be explained with reference to the accompanying drawings and the description below. The drawings are intended to explain the basic principle. Therefore, only those features relevant for illustrating the basic principle are shown. Unless stated otherwise, same reference characters designate the same features with the same meaning throughout the drawings.

FIGS. 1A and 1B, collectively as FIG. 1, illustrate a semiconductor arrangement that includes temperature sensors and an evaluation circuit coupled to the temperature sensors;

FIG. 2 shows a flow diagram illustrating the method for detecting a fault state;

FIGS. 3A and 3B, collectively as FIG. 3, for a first example of a semiconductor arrangement illustrates temperatures of the different temperature sensors in a normal state (FIG. 3A) and in a fault state (FIG. 3B);

FIGS. 4A and 4B, collectively as FIG. 4, for a second example of a semiconductor arrangement illustrates temperatures of the different temperature sensors in a normal state (FIG. 4A) and in a fault state (FIG. 4B);

FIGS. 5A and 5B, collectively as FIG. 5, illustrates a semiconductor arrangement that has electrical contacts and temperature sensors arranged in the vicinity of the electrical contacts and that has other temperature sensors arranged distant to the electrical contact;

FIG. 6 illustrates the temperature in the semiconductor arrangement of FIG. 5 in a normal state;

FIG. 7 illustrates the semiconductor arrangement of FIG. 5 in a mechanical fault state in which one electrical contact is interrupted;

FIG. 8 illustrates the temperature in the semiconductor arrangement of FIG. 7;

FIG. 9 illustrates a further example of a semiconductor arrangement that has electrical contacts and temperature sensors;

FIG. 10 illustrates a further example of a semiconductor arrangement that includes electrical contacts and temperature sensors;

FIG. 11 illustrates an example of a semiconductor arrangement that includes a thermal contact and temperature sensor arrangement in the vicinity of the thermal contact;

FIG. 12 illustrates a further example of a semiconductor arrangement;

FIG. 13 illustrates a first example of the evaluation circuit;

FIG. 14 illustrates a timing diagram of a temperature measurement signal occurring in the evaluation circuit of FIG. 13;

FIG. 15 illustrates a second example of the evaluation circuit;

FIGS. 16A-16C, collectively as FIG. 16, illustrate the functionality of the evaluation circuit according to FIG. 15;

FIG. 17 illustrates a further example of the evaluation circuit;

FIG. 18 illustrates another example of the evaluation circuit;

FIG. 19 illustrates the functionality of the evaluation circuit of FIG. 18;

FIG. 20 illustrates a further example of the evaluation circuit;

FIGS. 21A and 21B, collectively as FIG. 21, illustrate the functionality of the evaluation circuit of FIG. 20 in the normal state; and

FIG. 22 illustrates the functionality of the evaluation circuit of FIG. 20 in the fault state.

### DETAILED DESCRIPTION OF ILLUSTRATIVE EMBODIMENTS

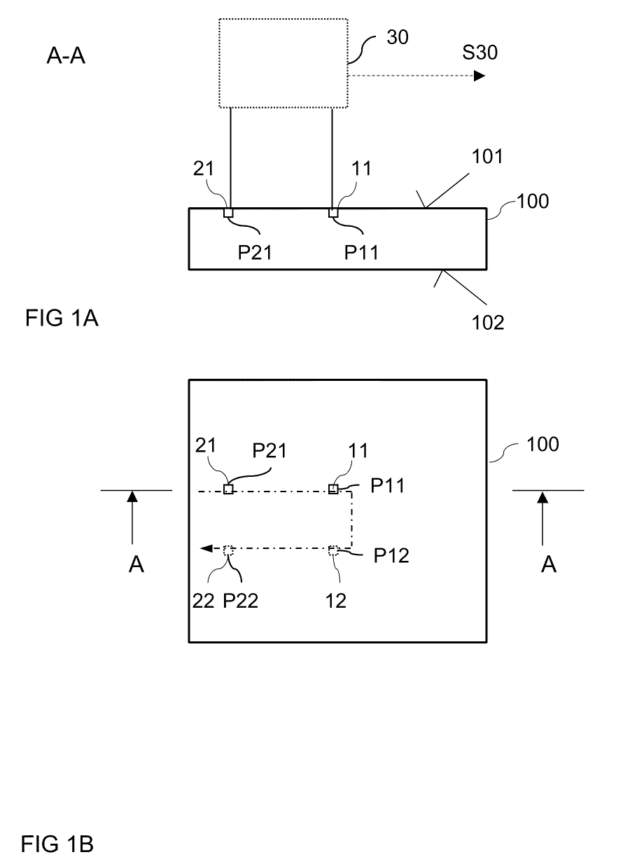

FIGS. 1A and 1B schematically show a semiconductor arrangement that includes a semiconductor body (die) 100. The semiconductor body 100 has a first side 101, that will be referred to as front side in the following, and a second side 102, that will be referred to as rear side in the following. FIG. 1A shows a vertical cross section of the semiconductor body 100, i.e., a cross section in a direction vertical to the front side 101 and the rear side 102. FIG. 1B shows a top view on the front side of the semiconductor body 100.

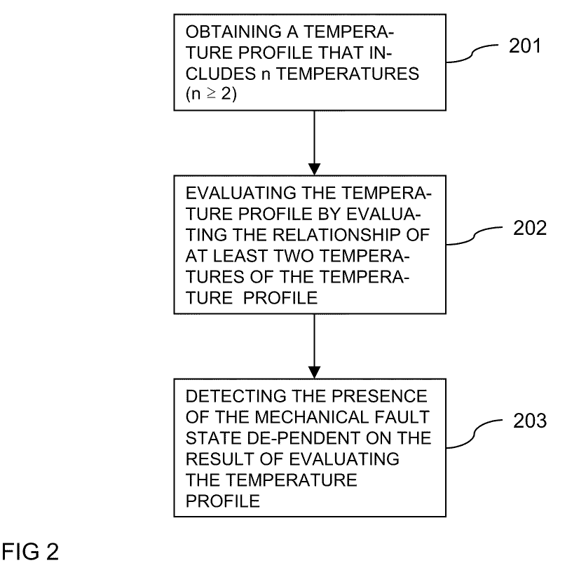

The semiconductor arrangement may assume one of a fault state and a normal state. Method steps for detecting the fault state will now be explained with reference to FIGS. 1 and 2, with FIG. 2 illustrating a flow diagram that includes different method steps.

Referring to FIG. 2, in a first method step 201 a temperature profile is obtained, the temperature profile including n temperatures with n≧2 by determining the temperatures at n different positions of the semiconductor arrangement. In FIGS. 1A and 1B, P11, P21 are the at least two different positions of the semiconductor arrangement at which the temperatures are determined for obtaining the temperature profile. These temperatures are determined using temperature sensors 11, 21 that are schematically shown in FIGS. 1A and 1B.

The temperature sensors 11, 21 can be any suitable temperature sensors that are adapted to sense the temperature at a given position of the semiconductor arrangement and to provide a temperature signal that is dependent on this temperature. Such temperature sensors are, for example, but are not limited to, diodes, bipolar transistors, and temperature dependent resistors. These components have electrical properties that are dependent on the temperature and are, therefore, suitable for providing electrical temperature measurement signals that are dependent on the temperature. Diodes, if loaded with constant current, have a forward voltage that is dependent on the temperature, with the voltage increasing with decreasing temperature, and, if loaded with a constant blocking voltage have a leakage or reverse current that is dependent on the temperature. Thus, either the forward voltage or the reverse current of diodes may be used as an electrical temperature dependent signal. While diodes have one integrated pn-junction, bipolar transistors have two pn-junctions, where one of these pn-junctions may be used as a temperature sensor. Either the forward voltage or the reverse voltage of this pn-junction may be used as the temperature sensor. Temperature dependent resistors are resistors that have an ohmic resistance that is dependent on the temperature. Dependent on the type of resistor, the resistance may increase with increasing temperature (PTC resistor) or may decrease with increasing temperature (NTC resistor). If temperature dependent resistors are used as temperature sensors these resistors may be loaded with a constant current and the voltage across the resistors may be used as an electrical current measurement signal.

The method for detecting a mechanical fault state further includes evaluating the temperature profile by evaluating the relationship of at least two of the n temperatures of the temperature profile, and detecting the presence of the fault state dependent on the result of evaluating the temperature profile.

The temperature profile obtained for the semiconductor arrangement includes information on the absolute temperatures of the semiconductor arrangement at the n different position, and further includes information on the relationship between the n individual temperatures. The method disclosed herein uses the fact that this relationship between the n individual temperatures is different for the normal state and for the fault state of the semiconductor arrangement.

In a first example obtaining the temperature profile includes determining the temperatures at positions of a first group of positions and determining the temperatures at positions of a second group of positions, each of these first and second groups including at least one position, and the temperatures at the positions of the first group being different from the temperatures at the positions of the second group in the normal state.

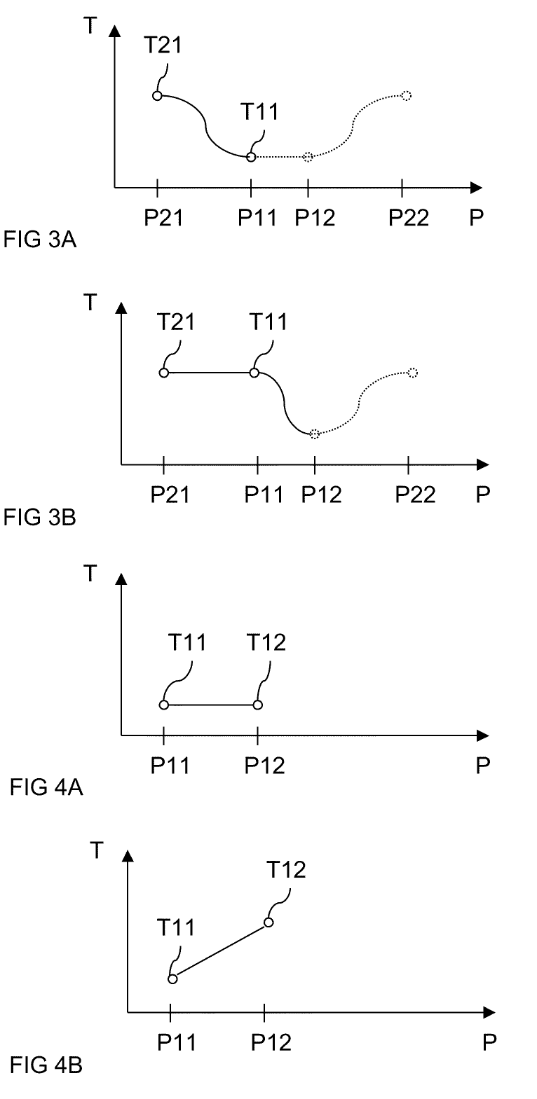

FIG. 3A illustrates an example of a temperature profile obtained for the normal state. In this example first position P11 being a position of the first group and second position P21 being a position of the second group. T11, T21 denote the temperatures of the first and second position P11, P21. In this example the first group of positions in the semiconductor arrangement are “cooler” positions, while the second group of positions are “hotter” positions in the semiconductor arrangement, if the semiconductor arrangement is in its normal state. “Cooler” positions are positions having a lower temperature as compared to “hotter” positions, which have a higher temperature.

In the fault state, the temperature T11 at the first position P11 approaches the temperature T21 at the second position P21. This is illustrated in FIG. 3B which shows the temperature profile in the fault state. In this example, in which the temperatures of the first and second groups are different in the normal state, evaluating the temperature profile may include calculating the difference between one of the temperatures T11 of the first group and one of the temperatures T21 of the second group. In this case the presence of the fault state is detected, if this difference or if the absolute value of this difference is less than a given reference value. In other words: The fault state (FS) is true (T) if

|T21−T11|<REF1 (1),

REF1 being the reference value.

In one example, reference value REF1 is dependent on at least one of the temperatures of the temperature profile. This takes into account that the absolute value of these temperatures in the normal state may influence the difference between these temperatures. This difference may, for example, decrease with decreasing absolute temperatures at the at least two positions P11, P21. The reference value REF1 therefore decreases with decreasing absolute value of at least one of the temperatures of the temperature profile.

In another example a fault state is detected, if both, the temperature T11 of the at least one position P11 and the temperature T21 of the at least one position P21 of the second group, are above a given temperature threshold REF2. This temperature threshold REF2 is selected such that in the normal state the temperatures of the cooler positions of the first group are below this threshold, while in the fault state, when one the temperatures of the first group approaches the temperatures of the second group, at least one of the temperatures of the first group rises above the second threshold REF2. This threshold REF2 is shown in a temperature profile of FIGS. 3A and 3B. In this example:

FS=T if (T11>REF2 and T21>REF2) (2).

Like in the example explained before, temperature threshold REF2 may be dependent on the temperature of at least one of the temperatures of the temperature profile, with this threshold REF2 increasing with increasing absolute value of the at least one temperature.

Referring to the previous discussion a temperature profile that includes two temperatures that have been measured at two different positions of the semiconductor arrangement are sufficient for detecting the fault state. However, the first and second groups of positions are not restricted to include only one position. Rather, these groups of positions may include any number of different positions, these positions being selected such, that in the normal state of the semiconductor arrangement the temperatures at the first positions are below the temperatures of the second positions. As an example FIG. 1B in dotted lines illustrates two additional positions: one additional position P12 of the first group; and one additional position P22 of the second group. The temperature profiles that are obtained by additionally using these two additional positions are illustrated in dotted lines in FIGS. 3A and 3B.

If the second group includes more than one position, evaluating the temperature profile may include: evaluating the difference between any of the temperatures of the second group with any temperature of the first group; or evaluating if any of the temperatures of the first group lies above a given threshold.

According to a further example obtaining the temperature profile includes determining the temperatures at positions of a first group of position, this first group including at least two positions and the temperatures at the positions of this group being within a given temperature range in the normal state. Referring to FIG. 1B positions P11 and P12 are positions of this first group. FIG. 4A illustrates the temperature profile obtained by determining the temperatures T11, T12 at these two positions P11, P12 in the normal state.

In the fault state, which is illustrated in FIG. 4B, the temperature of one of the positions, in the example T12, moves out of the given temperature range. This is equivalent to a fault state being detected (FS=T), if the absolute value of the difference between these two temperatures rises above a reference value REF3, i.e.,

FS=T if |T12−T11>REF3 (3).

Instead of evaluating the difference between the at least two temperatures the relationship between these temperatures and a further threshold value REF4 may be evaluated, where a fault state is detected (FS=T) if one of these temperatures increases above the threshold, i.e.,

FS=T if (T11>REF4 and T12>REF4) (4).

Like in the example explained before, reference value REF3 and threshold temperature REF4 may be dependent on the absolute value of at least one of the temperatures of the temperature profile. In this case reference value REF3 may increase with increasing absolute value of the temperature, and temperature threshold REF4 may increase with increasing absolute value of the temperature.

According to another example the mean value of the temperatures of the first group is calculated, if the first group of positions includes more than two positions. In this example the presence of a fault state is detected if the difference between one of the temperatures and the mean value is larger than a reference value. Further, the standard deviation of the temperatures of the first group may be calculated, where the reference value may be dependent on the standard, the reference value, for example, being larger than 1.5 times the standard deviation.

Besides the relationship between temperatures that have been obtained for the different positions, additionally the absolute value of one or more of these temperatures may be used in order to detect an overload condition of the semiconductor arrangement. Such overload condition is, for example, detected, if the temperature of at least one of the positions reaches a given temperature threshold.

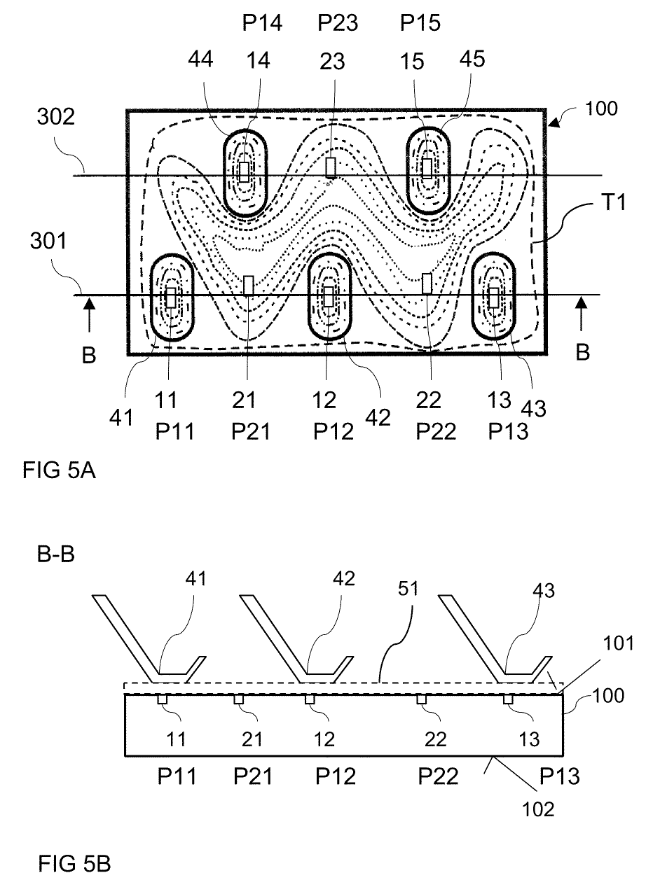

FIGS. 5A and 5B illustrate a top view and a cross sectional view of a semiconductor body 100 that has a number of electrical contacts 41-45 at its front side 101. These contacts are formed between a contact area and a connecting element that electrically contacts the contact surface. The contact area is either directly on the surface of the semiconductor body 100 or is on an optional metal layer 51 (shown in dashed lines in FIG. 5B) that is disposed on the front side 101 of the semiconductor body 100. The contacts are, for example, bond wire contacts. Such bond wire contacts are formed between the contact surface—which in this case is also referred to as a bond pad, and a bond wire as the connecting element. According to one example, a power semiconductor component, like a power MOSFET, a power IGBT or a thyristor is integrated in the semiconductor body 100, with the electrical contacts 41-45 contacting one of the load terminals of this power semiconductor component. In a MOSFET or a IGBT drain and source terminals are load terminals (which are also referred to as emitter and collector terminals in an IGBT), in a thyristor anode or cathode terminals are load terminals. The power semiconductor component further has control terminals, like a gate terminal in MOSFETs or IGBTs. However, these control terminals are not shown in FIGS. 5A and 5B.

For illustration purposes it may be assumed that a vertical MOSFET is integrated in the semiconductor body 100, this MOSFET having its source terminal at the front side and its drain terminal at the rear side of semiconductor body 100. A gate terminal may also be arranged at the front side of semiconductor body 100. However, this gate terminal is not shown in FIGS. 5A and 5B.

In power semiconductor components, like power MOSFETs, several electrical contacts are used for contacting one of the load terminals, these several contacts being necessary for sustaining high load currents flowing through such power semiconductor components.

Due to high temperatures that may occur in power semiconductor components these electrical contacts 41-45 are subject to wear or fatigue during the lifetime of the semiconductor arrangement. Such wear or fatigue may result in one of the bond wires lifting off, i.e., in an interruption of one of the electrical contacts. Interruption of one electrical contact results in a higher current flowing through the other contacts, which further accelerates the wear or fatigue process of these other contacts. Additionally, interruption of one contact may increase the current density in areas of the other contacts. This may result in an undesired local heating of the semiconductor arrangement in the area of these other contacts. Such undesired or uncontrolled heating may result in damage of the semiconductor arrangement and/or in damage of other circuitry connected to the semiconductor arrangement.

In order to avoid such damages it is desired to detect a fault state of the semiconductor arrangement in which one of the electrical contacts is interrupted. Such a fault state will be referred to as a “mechanical fault state” in the following.

Each of the methods disclosed so far may be used in detecting such mechanical fault state as will be explained in the following.

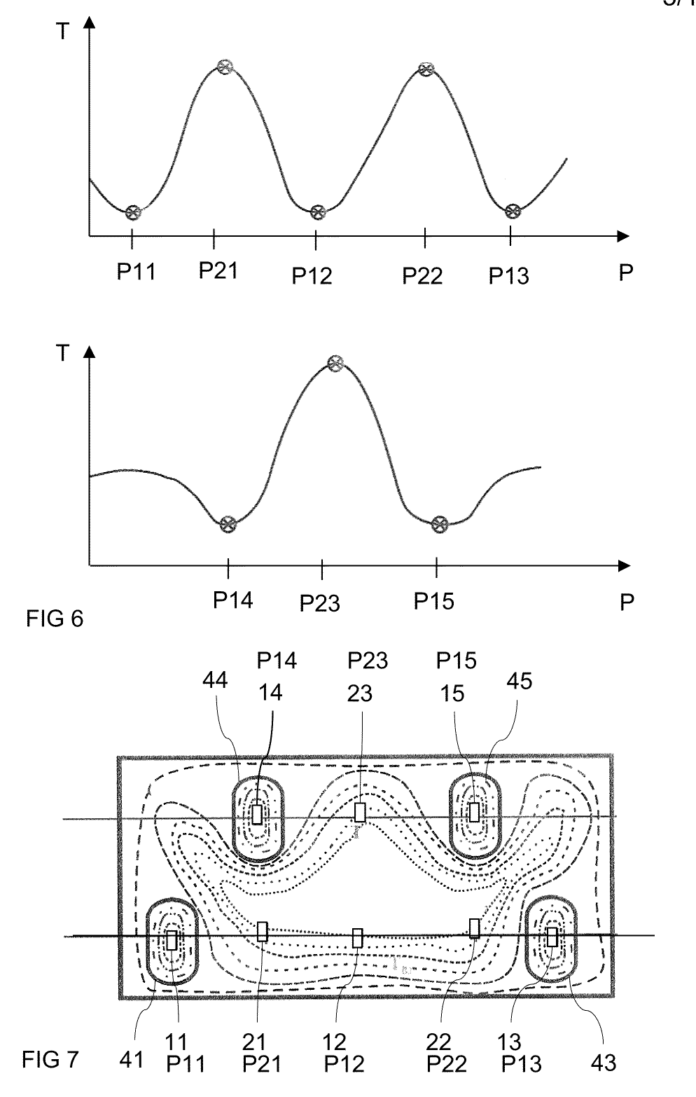

Examples of methods for detecting a mechanical fault state will now be explained with reference to FIGS. 6 to 8. In these methods the temperature in the vicinity of the electrical contacts 41-45 is evaluated. The first group of positions or the first group of sensors is therefore located below the electrical contacts 41-45 or at least in the vicinity of these electrical contacts 41-45. Dependent on the evaluation method to be used only the temperatures at the first positions are evaluated, or optionally a second group of positions, i.e., a second group of sensors, is used and the temperature profile obtained for the first and the second group of positions is evaluated. If a second group of positions is used, then these positions of the second group are located such that they have a larger distance to the electrical contacts 41-45 than the positions of the first group. FIG. 5A shows examples of these second positions 21-23.

FIGS. 5A and 6 illustrates the temperature distribution in the semiconductor body in the normal state. In FIG. 5A dashed and dotted lines illustrate isotherms, which are lines along which the temperature is constant. In the present example, the temperature increases starting from the edge region of the semiconductor body 100, i.e., an outermost isotherm has a lowest temperature T1, and an innermost isotherm has a highest temperature T2. As can be seen from FIG. 5A there are “cool spots” that are in the region of the electrical contacts 41-45. This is due to the fact that electrical contacts not only serve to electrically connect a connecting element, like a bond wire, to the semiconductor body but also provide a thermal contact to the semiconductor body 100, where such a thermal contact serves to dissipate heat from the semiconductor body 100. These thermal contacts will also be referred to as heat dissipating contacts in the following.

This is due to the fact that materials that are used for the connecting elements of the electrical contacts 41-45, like wire bonds, not only have a low electrical resistance but also have a low thermal resistance. In the normal state the temperature in the region or the vicinity of the electrical and thermal contacts 41-45 is therefore lower than in regions that are distant to these electrical and thermal contacts 41-45. In the normal state of the semiconductor arrangement the temperatures at the first positions P11-P15 that are arranged in the vicinity of the electrical contacts 41-45 are therefore lower than at the second positions P21-P23 that are distant to these electrical and thermal contacts 41-45.

FIG. 6 illustrates the temperature profile along lines 301, 302 of FIG. 5. These lines go through the individual positions of the first and second groups in the following order: P11-P21-P12-P22-P13 (line 301) and P14-P23-P15 (line 302). In the present example lines 301, 302 alternatingly go through positions of the first and second group, so that the temperature profile taken along these lines oscillates between higher and lower temperature values.

FIG. 7 illustrates the semiconductor arrangement of FIG. 5A in a fault state in which one 42 of the electrical and thermal contacts 41-45 is interrupted. Such interruption may result from fatigue-induced lifting off the bond wire that in the normal state makes this contact 42.

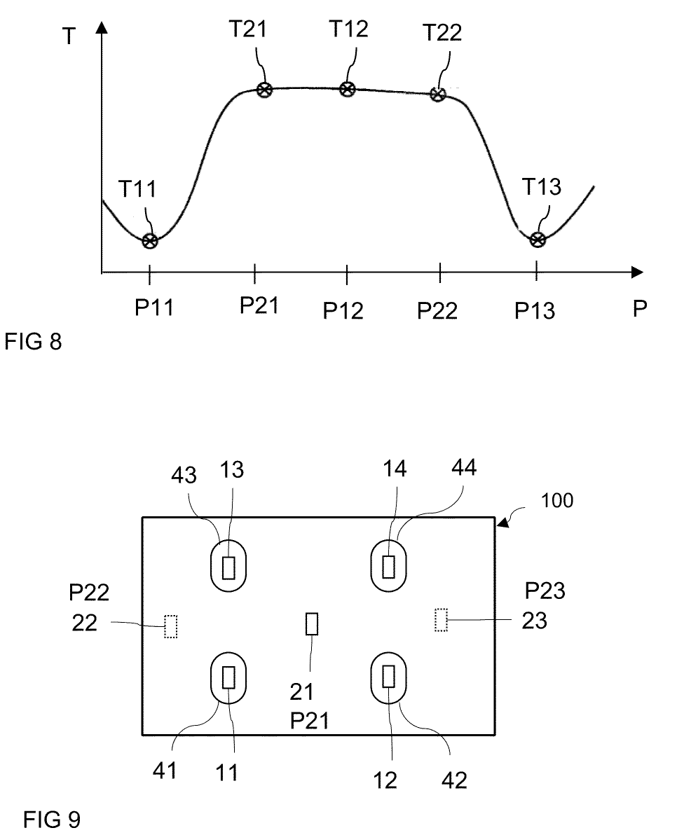

FIG. 8 illustrates the temperature profile taken along line 301 in the particular fault state of FIG. 7. As can be seen from the distribution of the isotherms in FIG. 7, the temperature T12 at position P12, that is below the interrupted electrical and thermal contact 42, significantly rises above the temperatures T11, T13 of positions P11, P13 of the first group that are below faultless contacts 41, 43. Temperature T12 at the position P12 of the faulty contact approaches the temperatures T21, T22 at the positions P21, P22 of the second group.

The fault state illustrated in FIG. 7 may either be detected by evaluating the temperatures at positions of the first group, only, or may be detected by evaluating temperatures of the first and the second group. In the first case, the temperatures of the first group may be compared to each other, where a fault state is detected, if one of these temperatures lies outside a given temperature range. This temperature range may be defined by any of the other temperatures of the first group, by a mean value of all of the temperatures of the first group, or by at least the mean value of a sub-group of temperatures of the first group. The temperature range is, for example defined to be a range that includes temperature values that lie within a given temperature window around the one of the other temperatures of the first group, by the mean value of all of the temperatures of the first group, or by at least a mean value of temperatures of a sub-group of the first group.

In the second case, the temperatures of the first group may be compared to temperatures of the second group, where a fault state is detected, if the difference between any of the temperatures of the first group and any of the temperatures of the second group is less than the given reference value.

It should be noted that the arrangement of electrical contacts illustrated in FIG. 5A is only an example. It goes without saying that dependent on the electrical requirements of the semiconductor component that is integrated in the semiconductor body any number of electrical contacts may be provided in any suitable configuration.

FIG. 9 illustrates a further example of a semiconductor arrangement that has a semiconductor body and a number of electrical contacts 41-44 on one of the surfaces of the semiconductor body. In the example according to FIG. 9 the electrical contacts are arranged at corners of an imaginary rectangle. The positions P11-P14 of the first group are located below these electrical contacts 41-44. Optionally the temperatures may be determined at positions P21-P22-P23 of a second group, where one P21 of these positions may be disposed in the center of the rectangle defined by the positions of the first group electrical contacts 41-44.

It should be noted that the explained detection method is not restricted to be used in detecting the interruption of electrical contacts in semiconductor arrangements that include power semiconductor components. This method may be used in any semiconductor arrangement that includes a semiconductor component that dissipates electrical power.

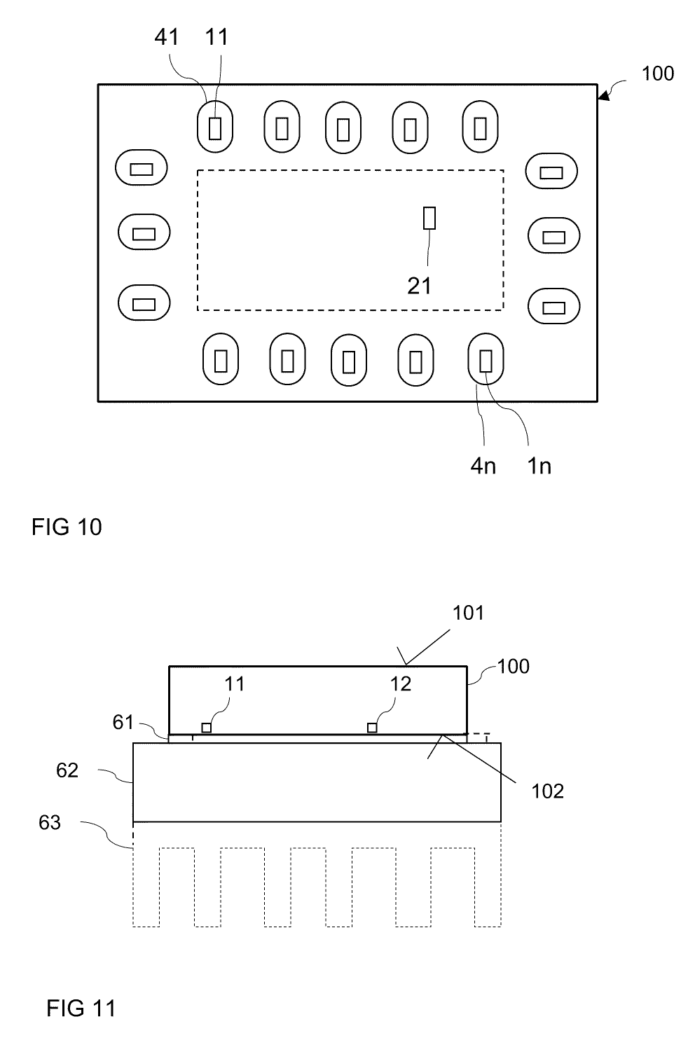

FIG. 10 shows a top view of a semiconductor body 100 that includes an integrated circuit, like a microcontroller, microprocessor or any other integrated circuit. The semiconductor body 100 includes a number of electrical contacts 41-4n, that are arranged along edges of the semiconductor body 100. Temperature sensors 11, In of the first group may be arranged below these electrical contacts 41-4n. In a first method only the temperature profile obtained for the positions of the first group is evaluated. In a second method detection of the fault state involves comparing temperatures of the first group with higher temperatures of the second group. In this case at least one temperature sensor 21 of the second group is arranged in a distance to these electrical contacts 41-4n, near the center of the semiconductor body 100.

Further, the method disclosed herein is not restricted to detect the interruption of thermal contacts that simultaneously are electrical contacts, like bond wire contacts, but may also be used in diagnosing the state of mere thermal contacts. FIG. 11 illustrates a semiconductor arrangement that includes a semiconductor body 100 that has its rear side 102 mounted to a carrier 62. The semiconductor body 100 is mounted to this carrier 62 using a solder or glue that has been applied between the rear side 102 of the semiconductor body 100 and the carrier 62. Carrier 62 serves to dissipate heat from the semiconductor body 100 and may be mounted to an optional cooling element 63 (shown in dashed lines). Solder or glue 61 provides a thermal contact between semiconductor body 100 and carrier 62. The thermal resistance of thermal contact layer 61, which will also be referred to as thermal contact in the following, influences the heat dissipation from the semiconductor body 100 to the cooling body 63.

The heat dissipating capabilities of the thermal contact layer 61 may negatively be influenced by different factors: First, thermal contact 61 may be subject to fatigue or wear during the lifetime of the semiconductor arrangement, resulting in cracks of the thermal contact layer 61. These cracks usually start at one location and may then extend completely through contact layer 61. In regions where those cracks start, the heat dissipating capabilities contact layer 61 is reduced, i.e., the thermal resistance of contact layer 61 is increased. Second, errors during the production process may occur, resulting in a misalignment of contact layer 61 and the semiconductor body 100. This misalignment is illustrated in dotted lines in FIG. 11. If semiconductor body 100 is misaligned relative to contact layer 61 regions of the semiconductor body 100 are not contacted by contact layer 61, which results in a higher thermal resistance between these regions and carrier 62. Third, errors during the production process may occur that result in voids or any other damages of contact layer 61, these voids or damages resulting in a locally increased thermal resistance of contact layer 61.

Those fatigue-induced or production induced failures of contact layer 61 may be detected by obtaining a temperature profile that includes temperatures taken at positions P11, P12 of a first group, these positions being arranged in the vicinity of thermal contact layer 61. In the normal state the temperatures at these positions of the first group are within a given temperature range. In case in contact layer 61 there is a failure that results in a locally increased thermal resistance 61, the temperature in the semiconductor body in the region of this failure will be higher than in the other region. This failure can be detected by obtaining the temperature profile at positions of the first group and by evaluating the temperature, in particular by evaluating if the individual temperatures taken at the positions of the first group are within the given temperature range.

The semiconductor body of FIG. 11 may include any kind of semiconductor component or integrated circuit. Dependent on the type of semiconductor component or integrated circuit that is integrated in the semiconductor body 100 the rear side 102 of semiconductor body 100 may form one of the electrical contacts of the semiconductor component. This is the case for vertical power components, like vertical MOSFETs, vertical IGBTs, or vertical thyristors. In these components the rear side 102 of the semiconductor body 100 usually forms a drain or cathode terminal of the component. In this case the function of contact layer 61 is not only to dissipate heat from semiconductor body 100 but also to electrically connect the rear side 102 of semiconductor body 100 to carrier 62. In this case carrier 62 is, for example, a lead frame.

In another example the arrangement shown in FIG. 11 includes semiconductor body 100 as a first semiconductor body and a second semiconductor body as the carrier 62. In this example second semiconductor 62 may include a power semiconductor component, like a MOSFET, an IGBT or a thyristor, and the first semiconductor body 100 may include a control circuit for controlling the power semiconductor component. In this case a thermally conducting layer may be disposed between the power semiconductor component and the semiconductor body that includes the control circuit. Using one of the methods as disclosed above mechanical faults of the thermally conducting may be detected as well as mechanical faults of electrical connections between the control circuit and the power semiconductor component.

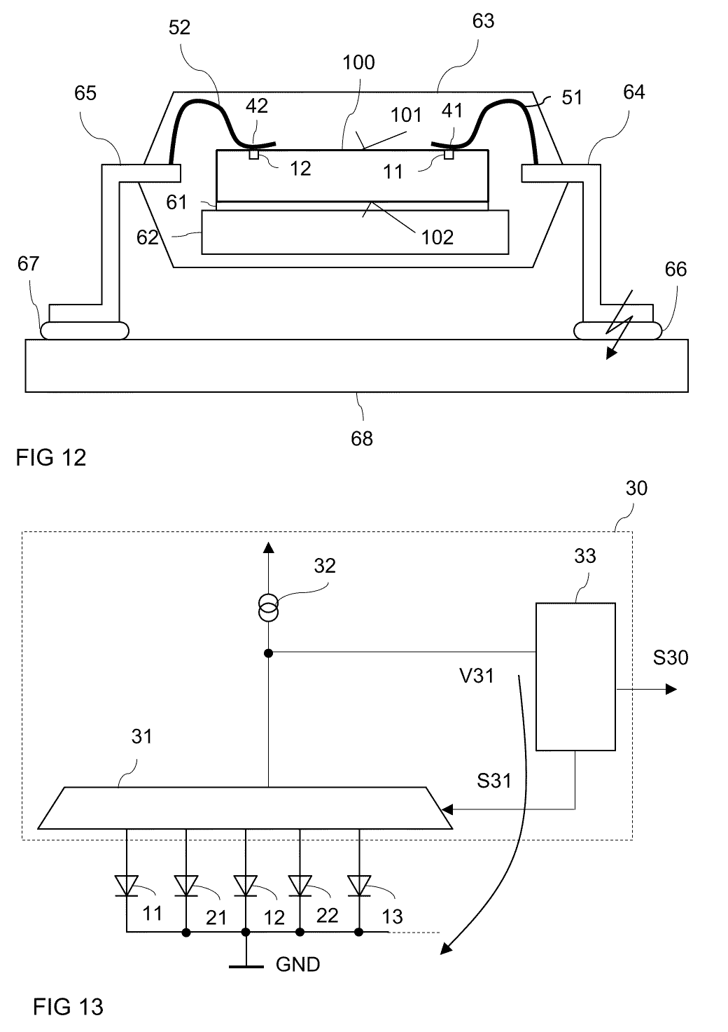

The methods disclosed herein not only allow for detecting the interruption of electrical contacts and/or fatigue of thermal contacts but also allow for detecting the interruption of electrical connections at positions distant to the semiconductor body 100. This will be explained with reference to FIG. 12. FIG. 12 illustrates a semiconductor arrangement including a semiconductor body 100. Semiconductor body 100 has a rear side mounted to a carrier 62, like a lead frame. Semiconductor body 100 and carrier 62 are surrounded by a package 63. Inside package 63 bond wires 51, 52 form electrical contacts with contact regions at the front side 101 of semiconductor body 100. These bond wires 51, 52 are connected to legs 64, 65 that extend into the package 63 and that serve to mount the semiconductor arrangement on a circuit board 68. These legs 64, 65 are, for example, mounted to the circuit board 68 using an electrically conducting glue or a solder. Bond wires 51, 52 that contact the semiconductor body 100 at contacts 41, 42, legs 64, 65 and solder or glue spots 66, 67 together form electrical connections to the semiconductor body 100. Interruption of one of these electrical connections at any point may result in a locally increased temperature of the semiconductor body 100 in this area in which the electrical connection contacts the semiconductor body 100. For illustration purposes it may be assumed that the first electrical connection is interrupted outside package 63, for example, due to a crack in solder or glue spot 66 or by lifting of leg 64 from the circuit board 68. This interruption reduces heat dissipation via the electrical connection, which results in an increasing temperature in the area of electrical contact 41. Such failure may be detected by the same methods explained with reference to FIGS. 5 to 8.

The method steps described above for evaluating the temperature profile may be performed using a detection circuit 30 that is illustrated in FIG. 1 in dashed lines. This detection circuit 30 is coupled to the individual temperature sensors that measure the temperature at the different positions for obtaining the temperature profile. According to one example the detection circuit 30 provides a status signal that assumes one of a first or second signal level, which will be referred to as fault state level and normal state level in the following, dependent on the state of the semiconductor arrangement. Detection circuit 30 may be integrated in the semiconductor 100. In this case providing only a “digital” status signal S30 instead of providing different temperature values that are evaluated “outside” the semiconductor body, requires only one additional terminal or pin at the semiconductor arrangement as compared to those arrangements that do not have the explained mechanical fault detection capability. Further, a digital signal transmission has a higher robustness concerning different offsets and is more reliable as compared to an analog signal transmission.

FIG. 13 illustrates an example of a detection circuit 30.

For a better understanding besides detection circuit 30 a number of temperature sensors 11, 12, 13, 21, 22 connected to the detection circuit 30 are also illustrated in FIG. 13. In the present example temperature sensors are diodes that are forward biased. Such forward biased diodes have a negative temperature coefficient, i.e., the voltage across these diodes decreases with increasing temperature. However, it goes without saying that any other type of temperature sensor may also be used, like sensors that have a positive temperature coefficient and, therefore, provide a temperature signal having an amplitude that increases with increasing temperature.

Detection circuit 30 comprises a multiplexer 31 that is connected in series to a current source 32 between a terminal for a first supply voltage V+ and the temperature sensors, the temperature sensors being connected between multiplexer 31 and a second supply potential, which is ground potential, for example. Multiplexer 31 receives a control signal S31 and is adapted to selectively connect one of the temperature sensors to current source 32. Current source 32 via multiplexer 31 drives a current through the selected temperature sensor, this current resulting in a voltage drop across the selected temperature sensor, the voltage drop being dependent on the temperature of the sensor. V31 in FIG. 13 denotes the voltage drop across the temperature sensor selected by multiplexer 31. In the present example voltage V31 also includes the voltage drop across multiplexer 31. However, this voltage drop is constant independent of which temperature sensor is selected and does therefore not negatively influence evaluation of the temperature signals. Detection circuit 30 further comprises an evaluation circuit 33 that receives voltage V31 provided by the series circuit with current source 32, multiplexer 31 and the temperature sensors.

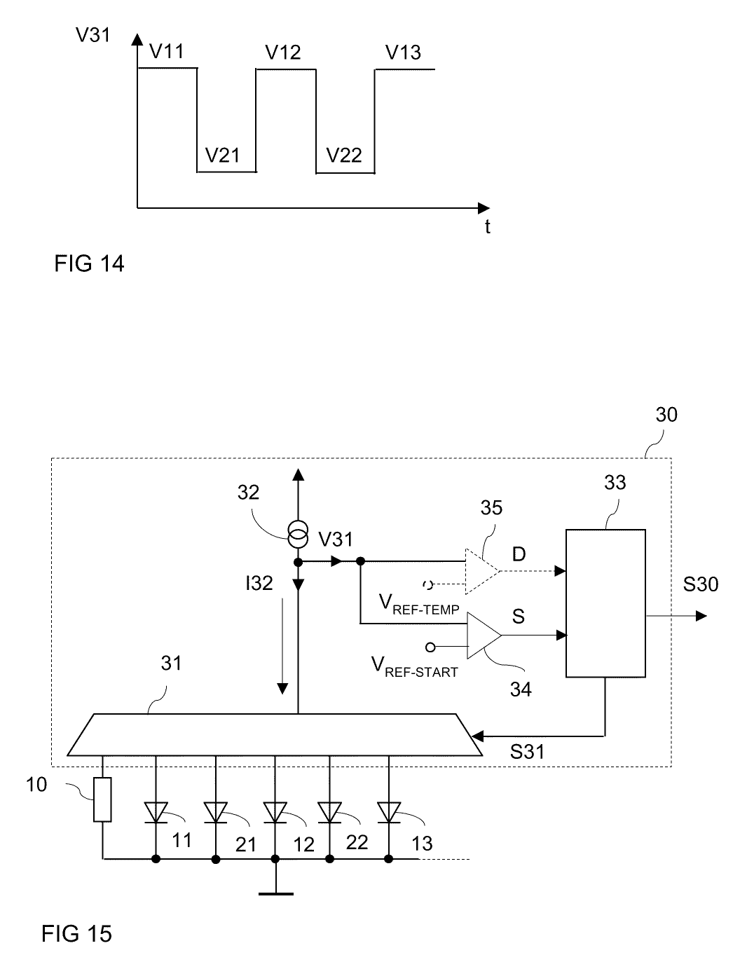

Temperature signal V31 includes a sequence of different temperature signals, each of these different temperature signals representing the voltage across one of the temperature sensors, and therefore representing the different temperatures measured by the different temperature sensors. FIG. 14 illustrates an example of temperature signal V31 provided to evaluation circuit 33. Temperature signal V31 in this example includes a sequence of different temperature signals V11, V21, V12, V22, V13, V23, . . . , each of these signals representing the voltage across one of the temperature sensors and, therefore, representing the temperature at one position within the semiconductor arrangement. Multiplexer 31 cyclically polls the temperature information provided by the individual temperature sensors, the duration of the individual temperature signals V11, V21, . . . within signal S31 is dependent on control signal S31 that switches multiplexer 31 between the different temperature sensors. Multiplexer 31 is, for example, adapted to switch between the different temperature sensors in a given order. The temperature information provided by the individual temperature sensors 11, 21, 12, . . . is then included in temperature signal V31 in this given order.

Evaluation circuit 33 is adapted to evaluate the temperature information it receives from the different temperature sensors according to one of the methods explained above. In this connection it should be mentioned that the temperature sensors connected to multiplexer 31 may either be temperature sensors of the first group and the second group, or may be temperature sensors of the first group, only. Dependent on the kind of temperature sensors that are connected to the detection circuit 30, evaluation circuit 33 performs one of the evaluation methods disclosed above. In the example according to FIG. 14 temperature signal V31 results from alternatingly polling temperature sensors of the first group and the second group, so that temperature signal V31 alternatingly assumes low and high signal levels, if no mechanical fault state has occurred. The high signal levels result from temperature sensors of the first group that are located at “cooler” positions, and the low signal levels result from temperature sensors of the second group that are located at “hotter” positions.

FIG. 15 illustrates an example of a detection circuit 30 that additionally to the temperature information provided by the individual temperature sensors provides a start information or start signal S to evaluation circuit 33. This start information S is a unique information that is different from the temperature information provided by any of the temperature sensors in either normal state or fault state. In the example according to FIG. 15 start information S is provided using a resistor 10 that is connected in parallel to temperature sensors 11, 12, 13, 21, 22 between the multiplexer 31 and the second supply potential (ground). The resistance of resistor 10 is, for example, selected such that a voltage across resistor 10 as resulting from current 132 flowing through the resistor 10 is higher than the voltage drop that can occur across any of the temperature sensors 11, 12, 13, 21, 22 for a given temperature range. If temperature sensors are used that have a negative temperature coefficient, resistor 10 is selected such, that the voltage drop across the resistor 10 is higher than the voltage drop across any of the temperature sensors at a minimum temperature. Alternatively the resistance of resistor 10 is, for example, selected such that a voltage across resistor 10 as resulting from current 132 flowing through the resistor 10 is lower than the voltage drop across any of the temperature sensors 11, 12, 13, 21, 22 at a maximum temperature. Instead of using a resistor any other passive component may be used for providing start signal S. An example of such other passive component is a Zener diode.

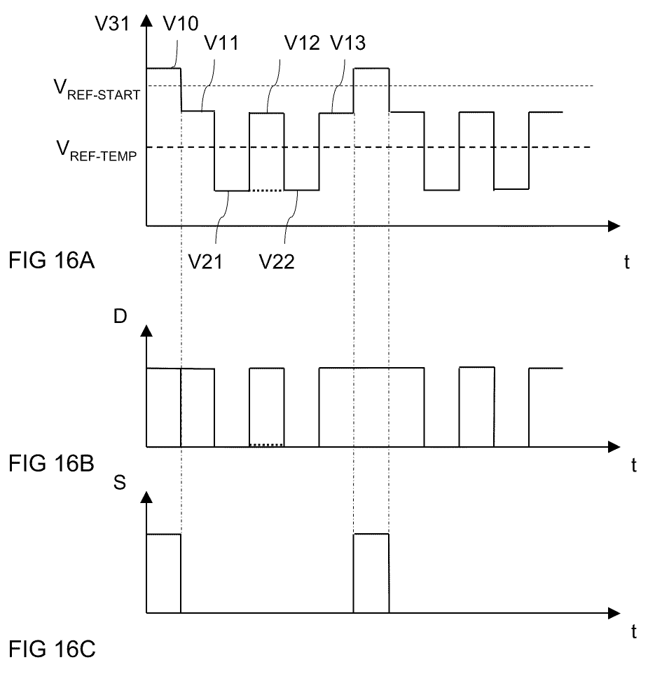

FIG. 16A illustrates an example of temperature signal V31 that is obtained in the detection circuit 30 according to FIG. 15. In this circuit, multiplexer 31 cyclically polls resistor 10 and temperature sensors 11, 12, 13, 21, 22. V10 in FIG. 16A denotes the voltage drop across resistor 10, which is higher than the voltage drop across temperatures sensors 11, 12, 13, 21, 22. The high voltage drop across resistor 10 marks the beginning of a new switching cycle. This high voltage drop can be evaluated using a comparator 34 that compares temperature signal V31 with a reference signal V_{REF-START}, this reference voltage V_{REF-START} being higher than the voltage drops that may occur across any of the temperature sensors 11, 12, 13, 21, 22 at a minimum temperature. The minimum temperature is the highest temperature that can occur in use of the semiconductor arrangement.

In the detection circuit of FIG. 15 comparator 34 provides start signal S. Referring to FIG. 16C, start signal S includes a signal pulse each time temperature signal V31 rises above reference value V_{REF-START}. Signal pulses of start signal S therefore mark the beginning of a new polling cycle. The signal information provided in the time period between two “start pulses” is the temperature information provided by the individual temperature sensors.

Optionally temperature signal V31 is pre-evaluated before feeding this signal to evaluation circuit 33. Pre-evaluation may be performed using a second comparator 35 (shown in dashed lines in FIG. 15) that compares temperature signal V31 with a temperature reference signal V_{REF-TEMP}. This temperature reference signal V_{REF-TEMP} being lower than the start reference signal V_{REF-START}. Second comparator 35 provides an output signal D that has a first signal level (a high-level in the present example), if temperature signal V31 is higher than reference signal V_{REF-TEMP}, and has a second signal level (a low signal level in the present example), if temperature signal V31 is lower than the reference signal V_{REF-TEMP}. Dependent on the type of temperature that is used, a high signal level of output signal D either indicates that the temperature as measured by one of the sensors is higher than a temperature threshold that is represented by reference signal V_{REF-TEMP}, or indicates that the temperature as measured by one of the sensors is lower than a temperature threshold that is represented by reference signal V_{REF-TEMP}. The first is true for sensors having a positive temperature coefficient, and the second is true for sensors having a negative temperature coefficient.

Such pre-evaluation may be applied in detection methods in which a fault state is detected by simply comparing temperatures provided by temperature sensors with a reference signal. FIG. 16A illustrates an example in which temperature sensors of a first and a second group are used and which temperature sensors of a first and second group are alternatingly polled by multiplexer 31. In this case temperature data signal D alternatingly assumes high and low signal levels between two start pulses, if the semiconductor arrangement is in its normal state. FIGS. 16A and 16B in dotted lines illustrate a fault state in which the temperature signal V12 of one of the temperature sensors of the first group rises above temperature reference value V_{REF-TEMP}, resulting in data signal D assuming a low signal level.

If a pre-evaluation of temperature signal V31 is performed, evaluation circuit 33 is adapted to compare the signal pattern in temperature signal D with a reference signal pattern that is internally stored in evaluation circuit 33, with this reference pattern representing the signal pattern that is obtained in the normal state of the semiconductor arrangement. In the example of FIG. 16, this reference signal pattern corresponds to the signal pattern that is shown in signal D in solid lines between two start pulses. A fault state is detected by evaluation circuit 33, if the signal pattern of temperature data signal D does not correspond to the reference signal pattern.

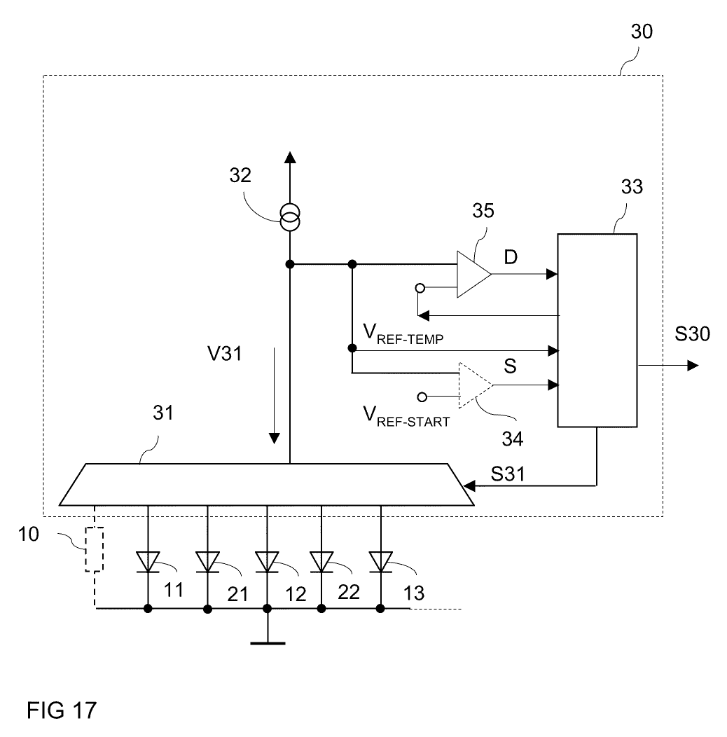

As explained above, in methods in which temperatures of the first group are compared to a reference value for detecting a fault state, the reference value may be adapted over time. FIG. 17 illustrates a detection circuit 30 in which evaluation circuit 33 provides the temperature reference signal V_{REF-TEMP}. Evaluation circuit 33 is, for example, adapted to generate this reference value V_{REF-TEMP} dependent on a number of temperatures provided by the first and/or second temperature sensors. If a pre-evaluation of the temperature signal V31 is performed, than evaluation circuit 33 besides temperature information signal D also receives temperature signal V31, that includes information on the absolute temperatures provided by the temperature sensors 11, 12, 13, 21, 22.

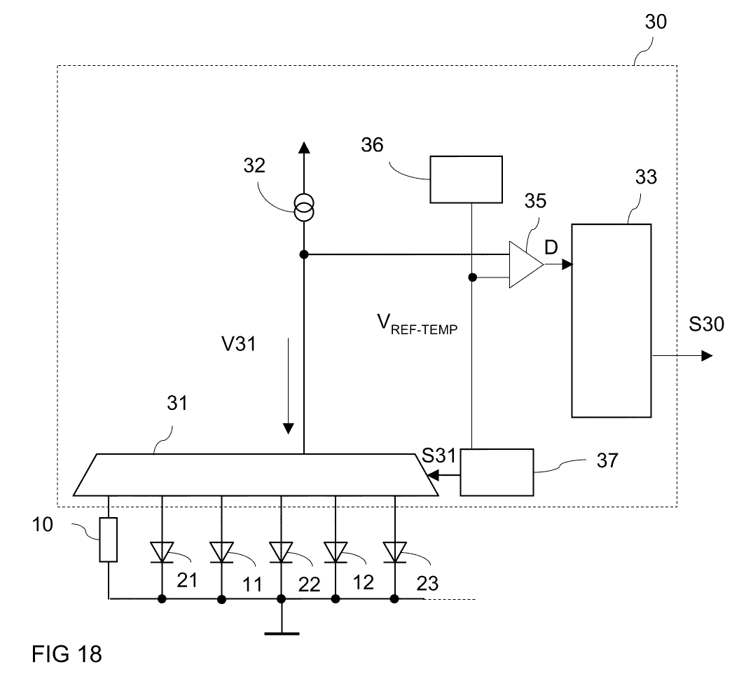

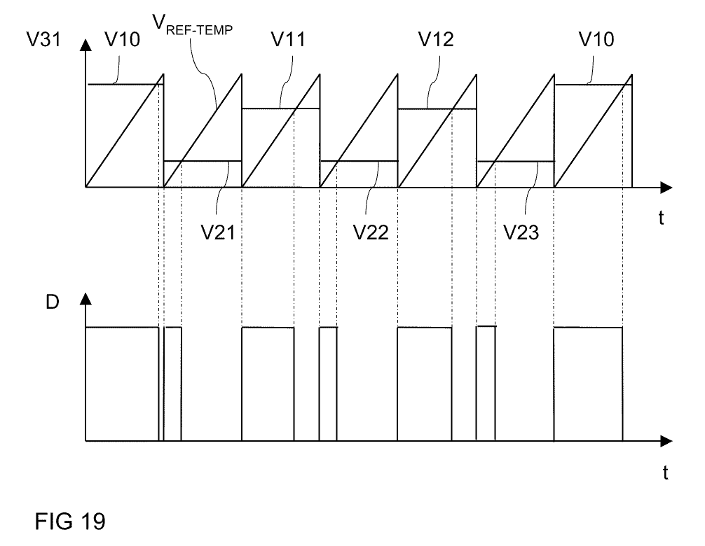

In the detection circuits 30 of FIGS. 15 and 17, pre-evaluation circuit 35 provides information on whether temperature signal V31 is higher or lower than reference signal V_{REF-TEMP}. Information on the absolute value of the individual temperature signal provided by temperature sensors 11, 12, 13, 21, 22 are not included in temperature data signal D. FIG. 18 illustrates a detection circuit 30 that includes a pre-evaluation circuit that provides a pulse-width modulated temperature data signal D. The duration of individual pulses of this data signal D includes an information on the absolute values of the temperature signals provided by temperature sensors 11, 12, 13, 21, 22. In this detection circuit 30 reference signal V_{REF-TEMP} is a sawtooth signal that is provided by a sawtooth generator 36. An example of a time characteristic of sawtooth signal V_{REF-TEMP} is illustrated in FIG. 19. FIG. 19 also illustrates an example of temperature signal V31 that is compared with reference signal V_{REF-TEMP} by comparator 35, and the temperature data signal D provided by comparator 35. As can be seen in FIG. 19, the duration of the individual pulses of data signal D is the longer, the higher the amplitude of the individual temperature signals V11, V21 . . . is.

Optionally resistor 10 may also be employed in connection with the detection circuit 30 of FIG. 18. The high voltage drop across resistor 10 results in signal pulses that are longer than the signal pulses resulting from the voltage drops across the temperature sensors. These long signal pulses therefore mark the beginning of a new polling cycle and can be evaluated in evaluation circuit 33.

In the detection circuit of FIG. 18, control signal S31 is provided by a circuit 37 that receives sawtooth circuit V_{REF-TEMP} and that generates the control signal S31 dependent on the sawtooth signal. Circuit 37 is, for example, adapted to switch multiplexer 31 each time a new period (sawtooth) of sawtooth signal starts.

The detection circuit 30 as explained with reference to FIG. 18, like any of the other detection circuits 30 that have been explained above, may completely be integrated in the semiconductor body of the semiconductor arrangement. In a further embodiment, evaluation circuit 33 is not integrated in the semiconductor body. In this embodiment evaluation circuit 33 may be a microcontroller or a part of a microcontroller that receives data signal D for evaluation and providing status signal S30.

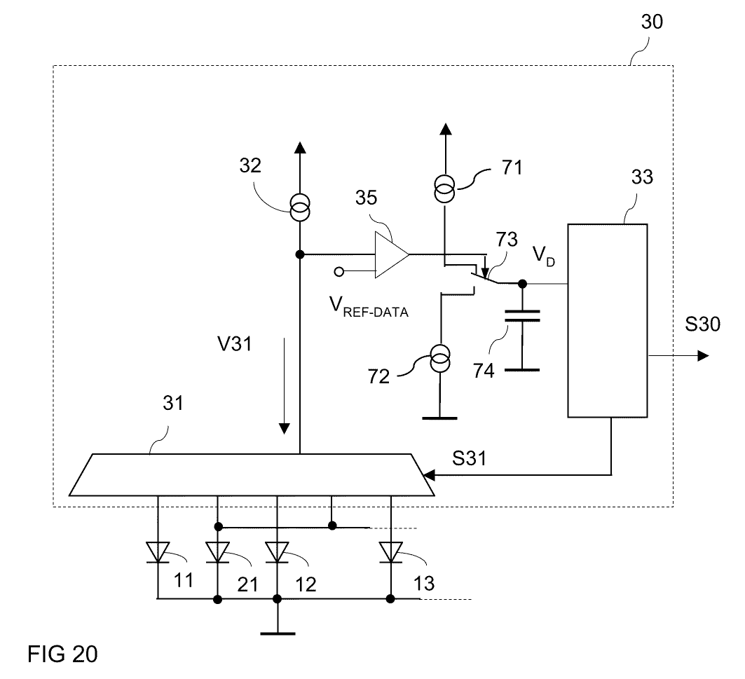

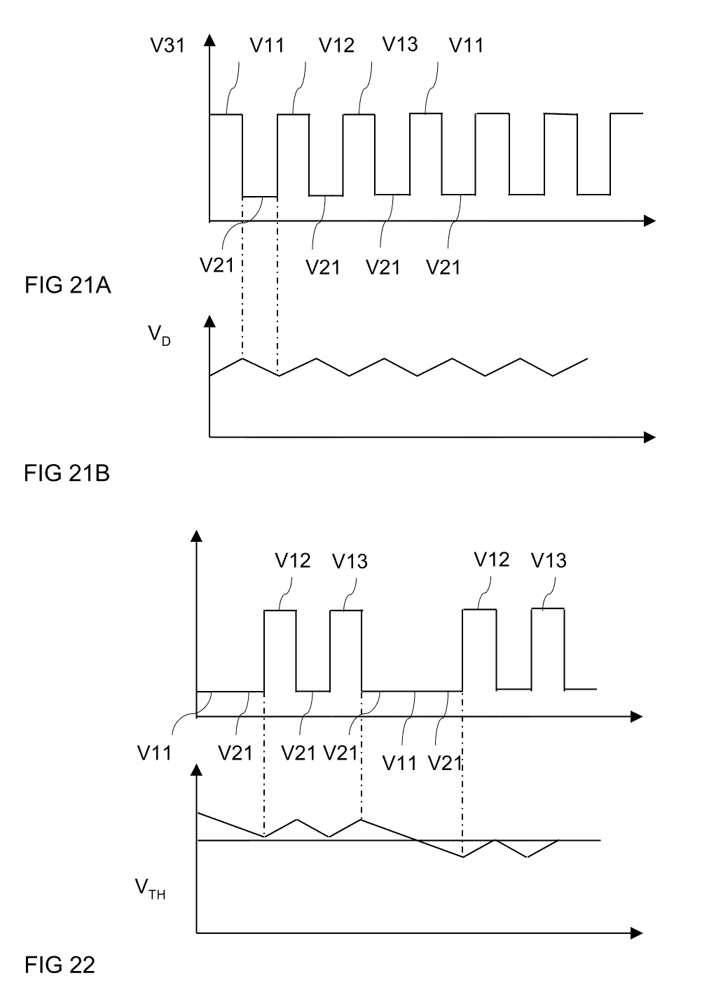

FIG. 20 illustrates a further example of a detection circuit 30. This detection circuit is, in particular, suitable for evaluating temperature profiles that in a normal state have at least two different temperatures, with one of these temperatures being below a reference value V_{REF-TEMP} and the other one of these temperatures being above the reference value V_{REF-TEMP}. In the example according to FIG. 20, the temperature profile is provided using one temperature sensor 21 of the second group and three temperature sensors 11, 12, 13 of the first group. However, one temperature sensor of the first group would be sufficient. In this circuit multiplexer 31 cyclically polls the individual temperature sensors in such a manner that alternatingly a temperature sensor of the first group and the temperature sensor of the second group are polled. An example of the temperature signal V31 by polling the individual temperature sensors in this manner is illustrated in FIG. 21A. This temperature signal V31 is compared to reference signal V_{REF-TEMP} by comparator 35. In the normal state temperature data signal D at the output of comparator 35 alternatingly includes signal pulses having high and low signal levels. This data signal D is integrated or low-pass filtered, a signal V_{D} resulting from this integration being provided to evaluation circuit 33. For integrating data signal D any suitable integrator may be used. In the example according to FIG. 20 the integrator includes a capacitor 74, two current sources 71, 72 and a switch 73. Switch 73 is controlled by data signal D and dependent on the data signal D connects capacitor 74 to first or second current source 71, 72. Capacitor 74 is charged, if the first current source 71 is active, and the capacitor 74 is discharged, if the second current source 72 is active. The currents provided by these two current sources 71, 72 are equal. In the normal state the integrated signal V_{D} therefore oscillates around a constant value. This can be seen from FIG. 21 in which the time characteristic of integrated signal V_{D} dependent on the temperature signal V31 is depicted.

FIG. 22 illustrates temperature signal V31 in a fault state, in which one of the first temperatures (VII in the present example) falls below the reference value V_{REF-TEMP}. As a result the overall duration for which first current source 32 charges capacitor 34 is decreased as compared to the normal state. Integrated signal V_{D} or the mean value of integrated signal V_{D} decreases over time. In this example evaluation signal circuit 33 is adapted to compare integrated signal V_{D} with a threshold signal V_{TH} and is adapted to detect a fault state, if integrated signal V_{D} falls below the reference signal.

It should be noted that features that have been explained with reference to one of the figures may be combined with any other feature that has been explained with reference to another figure, even if this has not been explicitly mentioned.

What is claimed is:

1. A method for detecting a mechanical fault state of a semiconductor arrangement, the method comprising:
obtaining a temperature profile that includes n temperatures, with n≧2, by determining a temperature with a temperature sensor at n different positions of the semiconductor arrangement;
evaluating the temperature profile by evaluating a relationship of at least two of the n temperatures of the temperature profile; and
detecting the presence of the fault state dependent on the result of evaluating the temperature profile.

2. The method of claim 1, wherein obtaining the temperature profile comprises:
determining the temperatures at positions of a first group of positions, the first group including at least one position, and determining the temperatures at positions of a second group of positions, the second group including at least one position, the temperatures at the positions of the first group being different from the temperatures at the positions of the second group in a normal state.

3. The method of claim 2, wherein the semiconductor arrangement includes at least one thermal contact and wherein the first group of positions are located closer to the at least one thermal contact than the second group of positions.

4. The method of claim 3, wherein the at least one thermal contact is also an electrical contact.

5. The method of claim 4, wherein the electrical contact comprises a bond wire contact.

6. The method of claim 3, wherein evaluating the temperature profile comprises evaluating the temperatures of one position of the first group of positions and one position of the second group of positions.

7. The method of claim 6, wherein the presence of the fault state is detected, if a difference between the temperatures of the one position of the second group and the one position of the first group is less than a given reference value.

8. The method of claim 7, wherein the reference value is dependent on the temperature of at least one of the temperatures of the one position of the second group and the one position of the first group.

9. The method of claim 6, wherein the presence of the fault state is detected, if both of the temperatures of the two positions are above a threshold value.

10. The method of claim 9, wherein the threshold value is dependent on the temperature of at least one of the temperatures of the one position of the second group and the one position of the first group.

11. The method of claim 2,
wherein the second group of positions includes two or more positions;
wherein evaluating the temperature profile comprises calculating a mean value of the temperatures of the first group of positions; and
wherein the presence of the fault state is detected if a difference between a mean value and a temperature of one position of the first group of positions is less than a given reference value.

12. The method of claim 1, wherein obtaining the temperature profile comprises:
determining temperatures at positions of a group of positions, the group including at least two positions, the temperatures at the positions of this group being within a given temperature range in a normal state.

13. The method of claim 12, wherein the presence of the fault state is detected, if one of the temperatures is outside the given temperature range.

14. The method of claim 13, wherein the given temperature range is dependent on a mean value of the temperatures.

15. The method of claim 12, wherein the temperature sensor includes at least two sensors and the semiconductor arrangement includes at least two thermal contacts and wherein the sensors are located near of the at least two thermal contacts.

16. The method of claim 15, wherein the thermal contacts are also electrical contacts.

17. The method of claim 16, wherein the electrical contacts comprise bond wire contacts.

18. The method of claim 12,
wherein the semiconductor arrangement comprises a carrier and a semiconductor body mounted to the carrier, and
wherein the positions are located in the vicinity of an interface between the semiconductor body and the carrier.

19. The method according to claim 1, wherein the semiconductor arrangement comprises a power semiconductor device.

20. The method according to claim 1, wherein the semiconductor arrangement comprises an integrated circuit.

21. A semiconductor arrangement comprising:
n temperature sensors, with n≧2, that are located at n different positions of the semiconductor arrangement and that provide temperature signals; and
an evaluation circuit coupled to the temperature sensors, the evaluation circuit being adapted to evaluate a relationship of at least two of the n temperatures of a temperature profile, the evaluation circuit providing a state signal that indicates one of a normal state or a mechanical fault state dependent on a result of evaluating the temperature profile.

22. The semiconductor arrangement of claim 21, wherein the temperature sensors comprise a first group of temperature sensors, the first group including at least one temperature sensor, and a second group of temperature sensors, the second group including at least one position, locations of positions of the first and second group of temperature sensors being such that temperatures at the positions of the first group are different from temperatures at the positions of the second group in the normal state.

23. The semiconductor arrangement of claim 22, further comprising at least one thermal contact, the positions of the first group of temperature sensors being located closer to the at least one thermal contact than the positions of the second group of temperature sensors.

24. The semiconductor arrangement of claim 21, wherein the temperature sensors are located such that temperatures at the positions are within a given temperature range in the normal state.

25. The semiconductor arrangement of claim 24, wherein the semiconductor arrangement includes at least two thermal contacts and wherein the temperature sensors are located in the vicinity of the at least two thermal contacts.
